(19) United States
(12) Patent Application Publication
(10) Pub. No.: US 2023/0057216 A1
(43) Pub. Date: Feb. 23, 2023

(54) SEMICONDUCTOR DEVICE AND METHOD OF MANUFACTURING THE SAME

(71) Applicant: RENESAS ELECTRONICS CORPORATION, Tokyo (JP)

(72) Inventors: Makoto KOSHIMIZU, Tokyo (JP); Yasutaka NAKASHIBA, Tokyo (JP)

(21) Appl. No.: 17/876,085

(22) Filed: Jul. 28, 2022

(30) Foreign Application Priority Data
Aug. 20, 2021 (JP) 2021-134869

(51) Int. Cl. H01L 29/06; H01L 27/088; H01L 29/10; H01L 29/78; H01L 21/02; H01L 21/306; H01L 21/308; H01L 29/66

(52) U.S. Cl. CPC H01L 29/0661; H01L 27/088; H01L 29/063; H01L 29/1095; H01L 29/7816; H01L 21/02639; H01L 21/30604; H01L 21/308; H01L 29/66681

(57) ABSTRACT

A semiconductor device and a method of manufacturing the semiconductor device to achieve both of a high breakdown voltage and a low on resistance are provided. A semiconductor substrate includes a convex portion protruding upward from a surface of the semiconductor substrate. An n-type drift region is arranged on the semiconductor substrate so as to be positioned between a gate electrode and an n⁺-type drain region in plan view, and has an impurity concentration lower than an impurity concentration of the n⁺-type drain region. A p-type resurf region is arranged in the convex portion and forms a pn junction with the n-type drift region.

### CROSS-REFERENCE TO RELATED APPLICATION

This disclosure of Japanese Patent Application No. 2021-134869 filed on Aug. 20, 2021, including the specification, drawings and abstract is incorporated herein by reference in its entirety.

### BACKGROUND

The present invention relates to a semiconductor device and a method of manufacturing the same.

There are disclosed techniques listed below. [Non-Patent Document 1] R. Zhu et al., “A High Voltage Super-Junction NLDMOS Device Implemented in 0.13 μm SOI Based Smart Power IC Technology,” Proceedings of The 22nd International Symposium on Power Semiconductor Devices & ICs, Hiroshima

Conventionally, Non-Patent Document 1 discloses a configuration in which a super junction structure is applied to a LDMOS (Laterally Diffused Metal Oxide Semiconductor), for example.

In the configuration of Non-Patent Document 1, a repetitive structure of a p-type pillar region and an n-type pillar region is arranged on a surface of a semiconductor substrate between a source region and a drain region.

### SUMMARY

In the configuration described in Non-Patent Document 1, as the p-type pillar region is provided, an effective channel width to work as a MOS transistor is reduced. Therefore, it is difficult to reduce the on-resistance.

Other problems and novel features will become apparent from the description herein and from the accompanying drawings.

According to a semiconductor device according to one embodiment, a semiconductor substrate includes a convex portion protruding upward from a surface of the semiconductor substrate. A first region of a first conductivity type is arranged in the semiconductor substrate so as to be positioned between a gate electrode and a drain region in plan view, and has an impurity concentration lower than an impurity concentration of the drain region. A second region of a second conductivity type is arranged in the convex portion so as to form a pn junction with the first region.

According to a semiconductor device according to another embodiment, a semiconductor substrate includes a first convex portion and a second convex portion protruding upward from a surface of the semiconductor substrate. A resurf region of a first transistor is arranged in the first convex portion so as to form a pn junction with a drift region. A second source region and a second drain region of a second transistor are arranged in the second convex portion so as to be positioned at a height position different from a height position of the first source region and the first drain region of the first transistor.

According to a method of manufacturing a semiconductor device according to an embodiment, a semiconductor substrate including a convex portion protruding upward from a surface of the semiconductor substrate, a first region of a first conductivity type arranged below the convex portion, and a second region of a second conductivity type arranged in the convex portion so as to form a pn junction with the first region is formed. A gate electrode is formed on the surface of the semiconductor substrate. A source region and a drain region of a first conductivity type having an impurity concentration larger than an impurity concentration of the first region are formed on the semiconductor substrate so as to sandwich the first region.

According to the above-described embodiments, it is possible to obtain a semiconductor device and a method of manufacturing the same to achieve both of a high breakdown voltage and a low on-resistance.

### BRIEF DESCRIPTIONS OF THE DRAWINGS

FIG. 1 is a plan view illustrating a configuration of a semiconductor device in a chip state according to an embodiment.

FIG. 2 is a cross-sectional view illustrating a configuration of the semiconductor device according to the embodiment.

FIG. 3 is an enlarged cross-sectional view illustrating an enlarged portion of FIG. 2.

FIG. 4 is a plan view illustrating a configuration of the semiconductor device according to the embodiment.

FIG. 5 is a perspective view illustrating a configuration of the semiconductor device according to the embodiment.

FIG. 6 is a plan view illustrating a planar shape of a gate electrode.

FIG. 7 is a plan view illustrating a modification of the planar shape of the gate electrode.

FIG. 8 is a plan view illustrating a configuration in which a resurf region is electrically connected to the gate electrode.

FIG. 9 is a cross-sectional view illustrating a first step in a first example of a method of manufacturing the semiconductor device according to the embodiment.

FIG. 10 is a cross-sectional view illustrating a second step in the first example of the method of manufacturing the semiconductor device according to the embodiment.

FIG. 11 is a cross-sectional view illustrating a third step in the first example of the method of manufacturing the semiconductor device according to the embodiment.

FIG. 12 is a cross-sectional view illustrating a fourth step in the first example of the method of manufacturing the semiconductor device according to the embodiment.

FIG. 13 is a cross-sectional view illustrating a fifth step in the first example of the method of manufacturing the semiconductor device according to the embodiment.

FIG. 14 is a cross-sectional view illustrating a sixth step in the first example of the method of manufacturing the semiconductor device according to the embodiment.

FIG. 15 is a cross-sectional view illustrating a first step in a second example of the method of manufacturing the semiconductor device according to the embodiment.

FIG. 16 is a cross-sectional view illustrating a second step in the second example of the method of manufacturing the semiconductor device according to the embodiment.

FIG. 17 is a cross-sectional view illustrating a first step in a third example of the method of manufacturing the semiconductor device according to the embodiment.

FIG. 18 is a cross-sectional view illustrating a second step in the third example of the method of manufacturing the semiconductor device according to the embodiment.

FIG. 19 is a cross-sectional view illustrating a third step in the third example of the method of manufacturing the semiconductor device according to the embodiment.

FIG. 20 is a cross-sectional view illustrating a fourth step in the third example of the method of manufacturing the semiconductor device according to the embodiment.

FIG. 21 is a cross-sectional view illustrating a fifth step in the third example of the method of manufacturing the semiconductor device according to the embodiment.

FIG. 22 is a cross-sectional view illustrating a sixth step in the third example of the method of manufacturing the semiconductor device according to the embodiment.

FIG. 23 is a cross-sectional view illustrating a first step in a fourth example of the method of manufacturing a semiconductor device according to the embodiment.

FIG. 24 is a cross-sectional view illustrating a second step in the fourth example of the method of manufacturing the semiconductor device according to the embodiment.

FIG. 25 is a diagram illustrating equipotential lines of the semiconductor device according to the embodiment.

FIG. 26 is a diagram illustrating an impact ionization rate distribution of the semiconductor device according to the embodiment.

FIG. 27 is a cross-sectional view illustrating a configuration of a comparative example.

FIG. 28 is a graph illustrating a relation between an off-breakdown voltage BVdss and an on-resistance Rsp.

FIG. 29 is a cross-sectional view illustrating a configuration of an application example of the semiconductor device according to the embodiment.

### DETAILED DESCRIPTION

Hereinafter, embodiments of the present disclosure will be described in detail with reference to the accompanying drawings. In the specification and drawings, the same or corresponding components are denoted by the same reference numerals, and a repetitive description thereof is not repeated. In the drawings, for convenience of description, any configuration may be omitted or simplified. In addition, at least a part of an embodiment and each modification may be arbitrarily combined with each other.

Note that a semiconductor device of an embodiment described below is not limited to a semiconductor chip and it may be a semiconductor wafer before being divided into semiconductor chips. Also, the semiconductor chip may be a semiconductor package sealed with a resin. In addition, “plan view” in this specification means a viewpoint from a direction perpendicular to a surface of a semiconductor substrate.

<Configuration of Semiconductor Device in Chip State>

First, a configuration of a chip state as a configuration of a semiconductor device according to an embodiment will be described with reference to FIG. 1.

As illustrated in FIG. 1, a semiconductor device CHI according to the present embodiment is, for example, in a chip state, and includes a semiconductor substrate. On a surface of the semiconductor substrate, respective formation regions such as a driver circuit DRI, a pre-driver circuit PDR, an analog circuit ANA, a power supply circuit PC, a logic circuit LC, an input-output circuit IOC and so forth are arranged.

An LDMOS transistor is arranged in each of the driver circuit DRI and the power supply circuit PC, for example.

<Configuration of LDMOS Transistor>

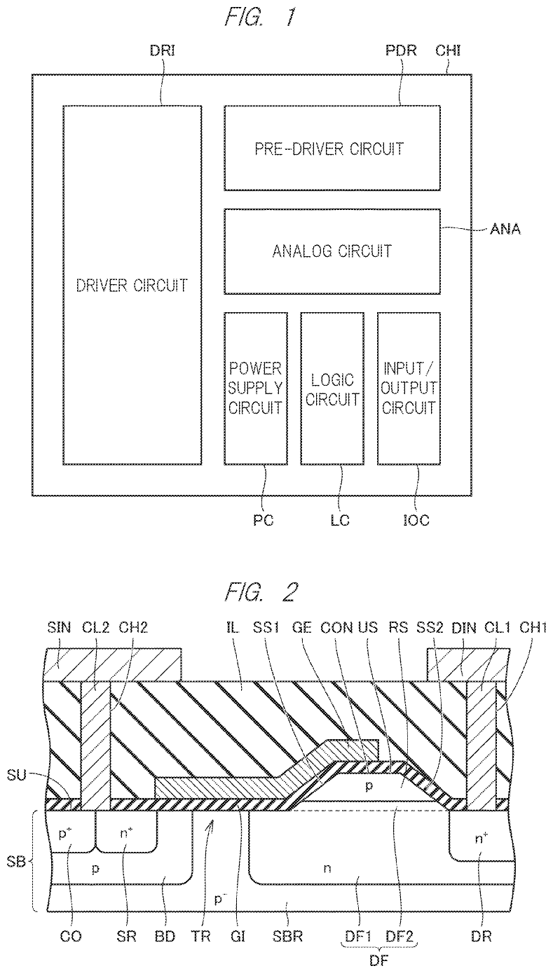

Next, a configuration of the LDMOS transistor used in the semiconductor device CHI of FIG. 1 will be described with reference to FIGS. 2 to 8.

Although the LDMOS transistor using a silicon oxide film as a gate insulating layer is explained in the description below, the gate insulating layer is not limited to the silicon oxide film and may be other insulating films. That is, the transistor used in the present embodiment is not limited to the LDMOS transistor, and it may be an LDMIS (Laterally Diffused Metal Insulator Semiconductor) transistor.

As illustrated in FIG. 2, a semiconductor substrate SB includes a surface SU and a convex portion CON. The convex portion CON is protruded upward from the surface SU. The convex portion CON, in a cross section, has both side surfaces SS1 and SS2 and an upper surface US. Each of the both side surfaces SS1 and SS2 is an inclined surface inclined with respect to the surface SU of the semiconductor substrate SB. The both side surfaces SS1 and SS2 are formed in a tapered shape in which a lateral distance between the both side surfaces SS1 and SS2 is decreased toward the top from the bottom in cross section.

A crystal plane of each of the both side surfaces SS1 and SS2 is {111} plane. The crystal plane of each of the both side surfaces SS1 and SS2 is, for example, (111) plane, but is not limited thereto, and may be a plane equivalent to (111) plane.

Each of the both side surfaces SS1 and SS2 is inclined at, for example, 54.7±2 degrees (52.7° or more and 56.7° or less) with respect to the surface SU of the semiconductor substrate SB. When a crystal plane of the surface of the semiconductor substrate SB is, for example, (100) plane, and the crystal plane of the both side surfaces SS1 and SS2 is, for example (111) plane, an angle formed between each of the both side surfaces SS1 and SS2 and the surface SU is theoretically 54.7°. In practice, however, due to manufacturing errors, etc., the angle between the surface SU and each of the both side surfaces SS1 and SS2 may vary within ±2°.

The upper surface US is connected to an upper end of each of the both side surfaces SS1 and SS2. The upper surface US is a flat surface and, for example, substantially parallel to the surface SU of the semiconductor substrate SB. Thus, a cross-sectional shape of the convex portion CON has a trapezoidal shape.

A p⁻-type substrate region SBR is arranged in the semiconductor substrate SB. An LDMOS transistor TR is arranged on the semiconductor substrate SB having the p⁻-type substrate region SBR.

The LDMOS transistor TR includes a p-type body region BD, an n-type drift region DF (first region), an n⁺-type source region SR, an n⁺-type drain region DR, a p-type resurf region RS (second region), a gate insulating layer GI, and a gate electrode GE.

The p-type body region BD is arranged in the semiconductor substrate SB and is in contact with the p⁻-type substrate region SBR. The p-type body region BD has a portion located on the surface SU of the semiconductor substrate SB. The p-type body region BD has a p-type impurity concentration larger than a p-type impurity concentration of the p⁻-type substrate region SBR.

The n-type drift region DF is arranged in the semiconductor substrate SB and forms a pn junction with the p⁻-type substrate region SBR. The n-type drift region DF is located between the gate electrode GE and the drain region DR in plan view. The n-type drift region DF includes a first semiconductor region DF1 and a second semiconductor region DF2. The first semiconductor region DF1 is located below the convex portion CON. The second semiconductor region DF2 is arranged on the first semiconductor region DF1 and located in the convex portion CON.

The second semiconductor region DF2 is extended upward from an upper end of the first semiconductor region DF1. An n-type impurity concentration of the first semiconductor region DF1 is equal to an impurity concentration of the second semiconductor region DF2. An n-type impurity concentration of each of the first semiconductor region DF1 and the second semiconductor region DF2 is, for example, 1×10=¹⁷/cm³. A boundary between the first semiconductor region DF1 and the second semiconductor region DF2 is an extension surface (broken line in the drawing) of the surface SU of the semiconductor substrate SB.

There may be organized discontinuities or an oxide at the boundary between the first semiconductor region DF1 and the second semiconductor region DF2. In addition, the first semiconductor region DF1 and the second semiconductor region DF2 are configured integrally with each other, and in some cases, the boundary between the first semiconductor region DF1 and the second semiconductor region DF2 cannot be recognized.

The n⁺-type source region SR is arranged in the semiconductor substrate SB, and forms a pn junction with the p-type body region BD. The n⁺-type source region SR is arranged on the surface SU of the semiconductor substrate SB.

The n⁺-type drain region DR is arranged in the semiconductor substrate SB, and is in contact with the n-type drift region DF. The n⁺-type drain region DR is arranged on the surface SU of the semiconductor substrate SB. The n-type drift region DF has an n-type impurity concentration lower than an impurity concentration of each of the n⁺-type source region SR and the n⁺-type drain region DR.

Between the n⁺-type source region SR and the n⁺-type drain region DR, the p-type body region BD, the p⁻-type substrate region SBR and the n-type drift region DF (first semiconductor region DF1) are sandwiched. The p-type body region BD, the p⁻-type substrate region SBR, and the n-type drift region DF (first semiconductor region DF) are arranged in this order from the n⁺-type source region SR to the n⁺-type drain region DR on the surface SU of the semiconductor substrate SB.

The p-type resurf region RS is arranged in the convex portion CON, and is located at the upper end portion of the convex portion CON. The p-type resurf region RS is arranged on the second semiconductor region DF2 and forms a pn junction with the second semiconductor region DF2 of the n-type drift region DF. The pn junction between the p-type resurf region RS and the second semiconductor region DF2 is located in the convex portion CON, and located above the surface SU of the semiconductor substrate SB.

A p-type impurity concentration of the p-type resurf region RS is equal to or larger than the n-type impurity concentration of the n-type drift region DF and it is 1×10¹⁷/cm³ or larger, for example. The p-type resurf region RS is electrically connected to either the gate electrode GE or a ground potential.

The gate electrode GE is arranged on the surface SU of the semiconductor substrate SB. The gate electrodes GE faces at least the p-type body region BD and a p⁻-type substrate region SBE via the gate insulating layer GI interposed therebetween. The gate electrode GE is formed of, for example, polycrystalline silicon in which impurities are implanted.

The gate electrode GE is formed on the convex portion CON via the gate insulating layer GI. The gate electrode GE covers the pn junction between the second semiconductor region DF2 and the p-type resurf region RS at the side surface SS1 of the convex portion CON. Thus, it is possible to mitigate the electric field between the second semiconductor region DF2 and the p-type resurf region RS. In addition, the gate electrode GE is extended to the upper surface US of the convex portion CON. The upper surface of the gate electrode GE located on the upper surface US of the convex portion CON is substantially parallel to the surface SU of the semiconductor substrate SB. Therefore, it is easy to connect a contact to the upper surface of the gate electrode GE located on the upper surface US of the convex portion CON.

A p⁺-type contact region CO is arranged on the surface SU of the semiconductor substrate SB so as to contact with each of the n⁺-type source region SR and the p-type body region BD. The p⁺-type contact region CO has a p-type impurity concentration larger than a p-type impurity concentration of the p-type body region BD.

On the surface SU of the semiconductor substrate SB, an interlayer insulating layer IL is arranged so as to cover the gate electrode GE and so forth. Contact holes CH1 and CH2 are provided in the interlayer insulating layer IL. The contact hole CH1 reaches the n⁺-type drain region DR from an upper surface of the interlayer dielectric layer IL. A conductive layer CL1 is embedded in the contact hole CH1. The contact hole CH2 reaches each of the n⁺-type source region SR and the p⁺-type contact region CO from an upper surface of the interlayer insulation layer IL. A conductive layer CL2 is embedded in the contact hole CH2.

On the interlayer insulating layer IL, wiring layers DIN and SIN are arranged. The wiring layers DIN and SIN are formed of a metal containing, for example, aluminum (Al) and so forth. The wiring layers DIN and SIN may be formed of a metal containing, for example, copper (Cu) and so forth. The wiring layer DIN is electrically connected to the n-type drain region DR via the conductive layer CL1. The wiring layer SIN is electronically connected to each of the n⁺-type source region SR and the p-type contact region CO via the conductive layer CL2.

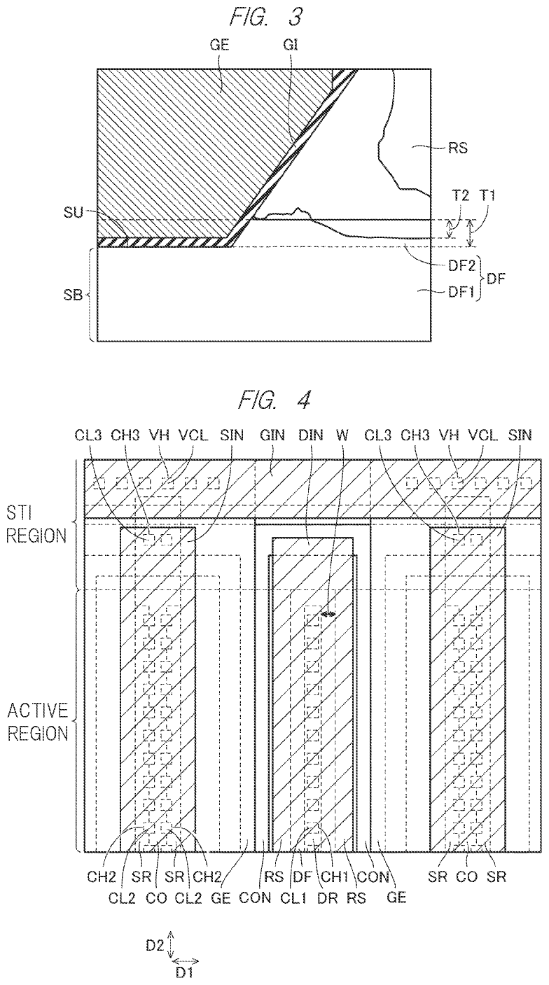

As illustrated in FIG. 3, the surface SU of the semiconductor substrate SB is located below by a distance T1 from a height position of the pn junction between the n-type drift region DF and the p-type resurf region RS. The distance T1 is, for example, about 0.05 μm. Here, the height position of the pn junction between the n-type drift region DF and the p-type resurf region RS is a height position at which the n-type impurity concentration of the n-type drift region DF and the p-type impurity concentration of the p-type resurf region RS are the same.

A depletion layer extends vertically from the pn junction between the n-type drift region DF and the p-type resurf region RS. In a state where no voltage is applied to each of the n-type drift region DF and the p-type resurf region RS, the depletion layer extends downward from the pn junction between the n-type drift region DF and the p-type resurf region RS to a distance T2 of about 0.03 μm. Therefore, by setting the distance T1 to a distance of, for example, about 0.05 μm, the depletion layer extended downward from the pn junction between the n-type drift region DF and the p-type resurf region RS does not extend to the first semiconductor region DF1. Thus, the depletion layer does not extend below the height position of the surface SU of the semiconductor substrate SB.

As illustrated in FIG. 4, the semiconductor substrate SB includes an active region and an STI (Shallow Trench Isolation) region. Impurity regions configuring the LDMOS transistor are arranged in the active region. The STI region is arranged so as to surround the active region in plan view.

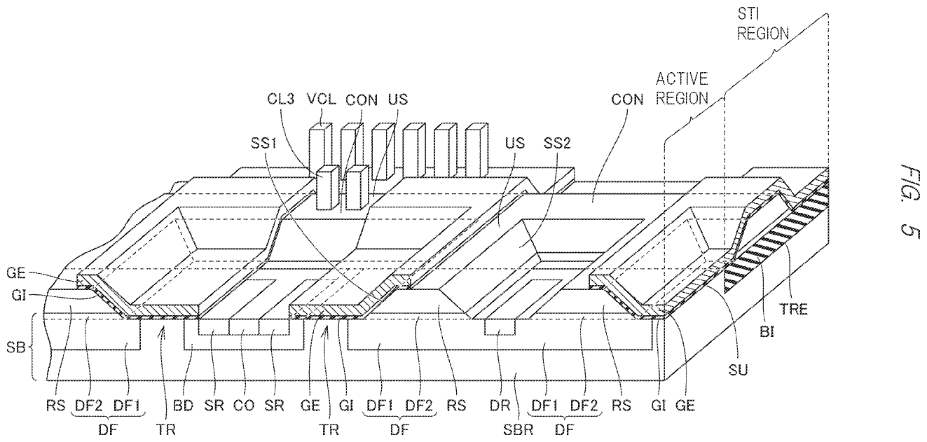

As illustrated in FIG. 5, an STI structure that is an element isolation structure is arranged on the surface SU of the semiconductor substrate SB in the STI region. The STI structure includes a trench TRE and an insulating layer BI. The trench TRE extends from the surface SU of the semiconductor substrate SB to a predetermined depth. The insulating layer BI is embedded in the trench TRE.

As illustrated in FIG. 4, the convex portion CON is arranged so as to individually surround each of the n⁺-type drain region DR and the n⁺-type source region SR in plan view. Therefore, the p-type resurf region RS arranged in the convex portion CON is also arranged so as to individually surround each of the n-type drain region DR and the n⁺-type source region SR in plan view.

Each of the convex portion CON and the p-type resurf region RS has a ladder shape having, for example, a plurality of slits in plan view. In plan view, the n⁺-type drain region DR is arranged in the first slit of the p-type resurf region RS. In plan view, the n⁺-type source region SR is arranged in the second slit adjacent to the first slit. In this manner, in such the plurality of slits, the n⁺-type drain region DR and the n⁺-type source region SR are alternately arranged.

In plan view, the n⁺-type drain region DR is arranged having a distance W from the p-type resurf region RS. The distance W is the distance when projected in plan view. The distance W is, for example, about 0.2 μm or more.

The gate electrode GE is electrically connected to the wiring layer GIN via the conductive layer VCL. The conductive layer VCL is embedded in a via hole VH provided in the interlayer insulating layer IL (FIG. 2). The wiring layer GIN is a conductive layer that is formed to be isolated from the same layer as the wiring layers DIN and SIN, and is formed of a metal containing, for example, aluminum and so forth.

The p-type resurf region RS arranged in the convex portion CON is electrically connected to the wiring layer SIN via a contact conductive layer CL3. The contact conductive layer CL3 is embedded in the contact hole CH3 provided in the interlayer insulating layer IL (FIG. 2). The wiring layer SIN is electrically connected to the n⁺-type source region SR via the conductive layer CL2 as described above. In this manner, the p-type resurf region RS is electrically connected to the n⁺-type source region SR via the contact conductive layer CL3, the wiring layer SIN, and the conductive layer CL2, and the p-type resurf region RS is grounded.

The contact conductive layer CL3 is arranged in a second direction D2 that is perpendicular to a first direction D1 toward the n⁺-type drain region DR with respect to the n-type source region SR in plan view.

As illustrated in FIG. 5, the contact conductive layer CL3 is connected to the upper surface US of the convex portion CON avoiding the both side surfaces SS1 and SS2 of the convex portion CON. In addition, the conductive layer VCL is connected to the flat upper surface of the gate electrode GE avoiding the portion of the gate electrode GE located directly above the both side surfaces SS1 and SS2 of the convex portion CON. The conductive layer VCL is located on the outer peripheral side than the convex portion CON in plan view.

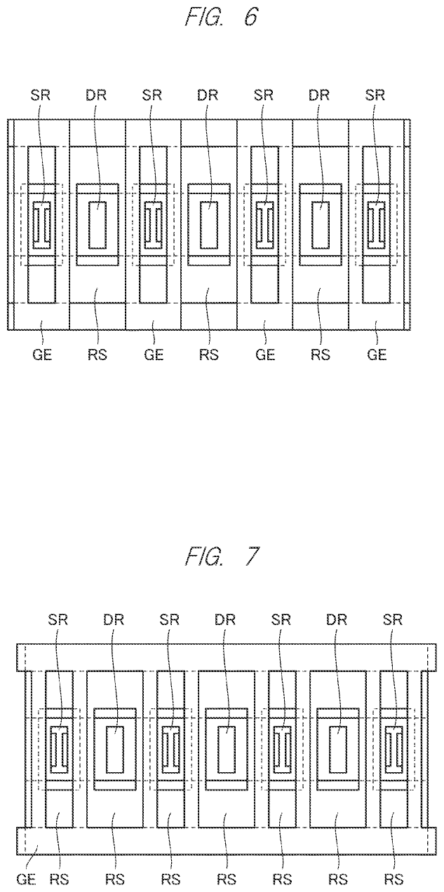

As illustrated in FIG. 6, the gate electrode GE has a ring shape in plan view. The ring-shaped gate electrode GE surrounds the entire periphery of the n⁺-type source region SR in plan view. Also, the gate electrode GE surrounding the one n-type source region SR and the gate electrode GE surrounding the other n⁺-type source region SR are isolated from each other.

As also illustrated in FIG. 7, the gate electrode GE may have a ladder shape in plan view. In this case, the gate electrode GE configures a ladder shape by connecting a portion surrounding the whole periphery of the n⁺-type source region SR and a portion surrounding the whole periphery of the n⁺-type drain region DR in plan view. For this reason, the n⁺-type drain region DR and the n⁺-type source region SR are alternately arranged in a plurality of slits of the ladder shape.

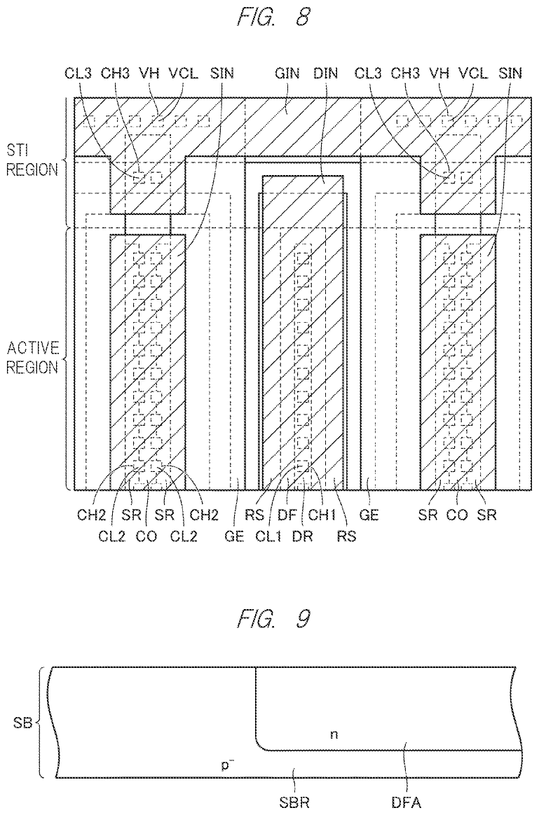

In the above description, the case where the p-type resurf region RS is at the ground potential has been described, but the p-type resurf region RS may be at the same potential as a potential of the gate electrode GE. In this case, as illustrated in FIG. 8, the contact conductive layer CL3 connected to the flat upper surface of the convex portion CON is connected to the wiring layer GIN. In this manner, the p-type resurf region RS is electrically connected to the gate electrode GE via the contact conductive layer CL3, the wiring layer GIN, and the conductive layer VCL.

In the above description, although the configuration in which a lower end of the n-type drift region DF is in contact with the p⁻-type substrate region SBR has been described in FIG. 2, a p-type resurf region in contact with the lower end of the n-type drift region DF may be added. The additional p-type resurf region is located between the p⁻-type substrate region SBR and n-type drift region DF and forms a pn junction with the n-type drift region DF by having a contact with the lower end of the n-type drift region DF. By adding the p-type resurf region in contact with the lower end of the n-type drift region DF, the resurf effect is more significantly exhibited.

<Method of Manufacturing LDMOS Transistor>

Next, four methods of manufacturing LDMOS transistors according to the present embodiment will be described with reference to FIGS. 9 to 24.

### First Example of Manufacturing Method

As illustrated in FIG. 9, an n-type region DFA is formed in the p⁻-type substrate region SBR of the semiconductor substrate SB. Thereafter, an STI structure (not illustrated) is formed on the surface of the semiconductor substrate SB.

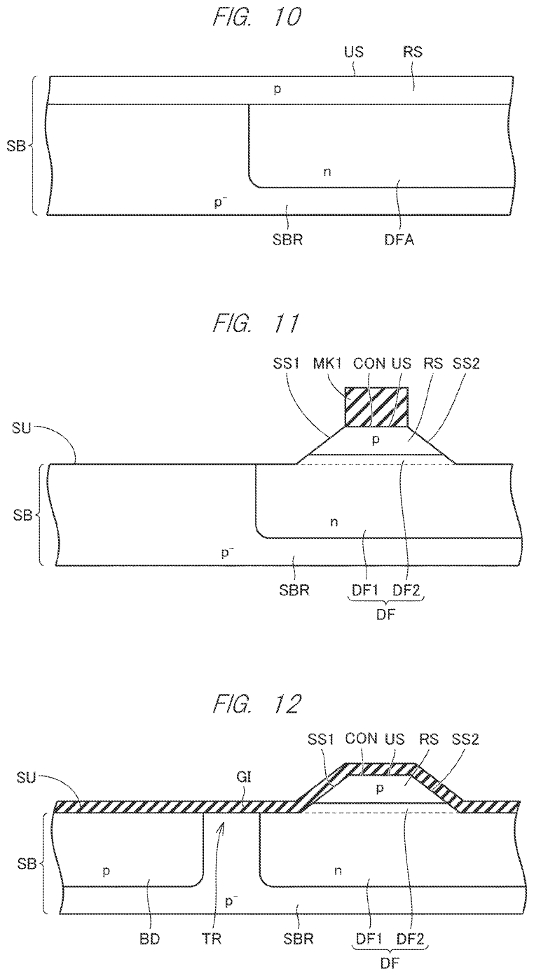

As illustrated in FIG. 10, by an epitaxial growth method, a p-type epitaxial layer RS is formed on the surface of the semiconductor substrate SB. In this epitaxial growth method, the p-type epitaxial layer RS of a single crystal is grown on the surface of the single crystal silicon of the semiconductor substrate SB, and the p-type epitaxial layer RS of polycrystal is grown on the STI structure.

As illustrated in FIG. 11, a masking layer MK1 formed of, for example, a silicon oxide film is formed on the p-type epitaxial layer RS. The masking layer MK1 is formed to be located at least in a region directly above the n-type region DFA. Using the masking layer MK1 as a mask, an anisotropic wet etching is performed using, for example, a TMAH (tetramethylammonium hydroxide) aqueous solution. By this etching, a surface of the semiconductor substrate SB is selectively removed to a position deeper than the pn junction between the p-type epitaxial layer RS and the n-type region DFA.

In this anisotropic wet etching, as the dependence on crystal orientation is large, an etching rate in the <100> direction is faster in the case of silicon, and an etching rate in the <111> direction is the slowest. Therefore, by an anisotropic wet etching using a silicon substrate of (100) plane, the convex portion CON having the both side surfaces SS1 and SS2 of (111) plane is formed. In this manner, the trapezoidal convex portion CON including the both side surfaces SS1 and SS2 inclined with respect to the surface SU of the semiconductor substrate SB and the upper surface US connecting the upper ends of the both side surfaces SS1 and SS2 is formed.

By the above-described etching, the p-type resurf region RS formed of the p-type epitaxial layer RS is formed in the upper portion of the convex portion CON. Further, the n-type drift region DF formed of an n-type region is formed in the lower portion of the convex portion CON. The n-type drift region DF can be distinguished into the first semiconductor region DF1 located below the surface SU of the semiconductor substrate SB, and the second semiconductor region DF2 located above the surface SU of the semiconductor substrate SB. Thereafter, the masking layer MK1 is removed.

As illustrated in FIG. 12, a p-type body region BD is formed as a p-type well region in the semiconductor substrate SB. Thereafter, the surface SU of the semiconductor substrate SB is oxidized. In this manner, so as to cover the surface SU of the semiconductor substrate SB and the surface of the convex portion CON, the gate insulating layer GI formed of a silicon oxide film is formed.

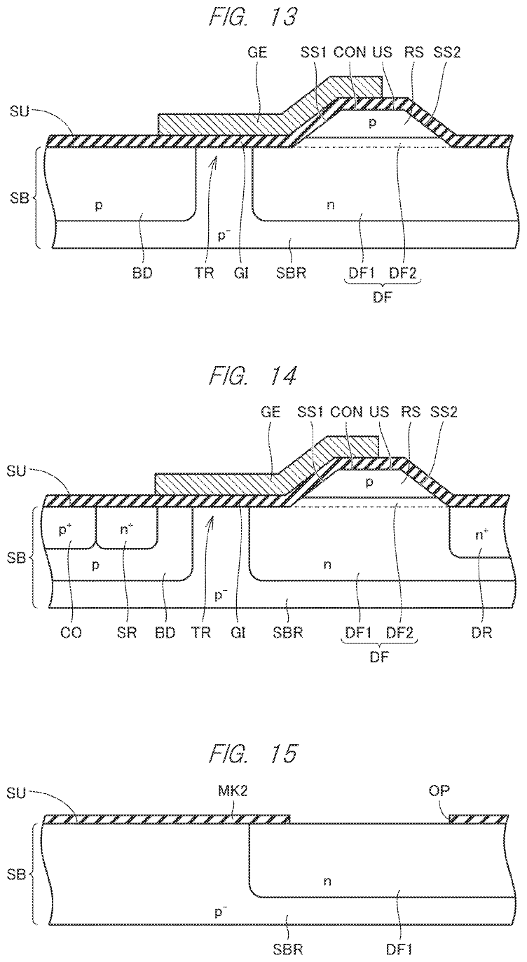

As illustrated in FIG. 13, a polycrystalline silicon layer GE into which impurities are implanted is formed on the gate insulating layer GI. The polycrystalline silicon layer GE is patterned by a photolithography technique and an etching technique to form the gate electrode GE.

As illustrated in FIG. 14, n-type impurities are ion-implanted into the surface SU of the semiconductor substrate SB to form an n⁺-type source region SR and an n⁺-type drain region DR in the surface SU of the semiconductor substrate SB. In addition, p-type impurities are ion-implanted into the surface SU of the semiconductor substrate SB to form a p⁺-type contact region CO in the surface SU of the semiconductor substrate SB.

As illustrated in FIG. 2, after this, the interlayer insulating layer IL is formed so as to cover the surface of the semiconductor substrate SB. The contact holes CH1 and CH2 are formed in the interlayer insulating layer IL. The conductive layers CL1 and CL2 are formed to be embedded in the contact holes CH1 and CH2, respectively. Thereafter, the wiring layers DIN and SIN are formed on the interlayer insulating layer IL. In this manner, the LDMOS transistor TR according to the present embodiment is formed.

### Second Example of Manufacturing Method

A second example of the manufacturing method takes the same process as the first example of the manufacturing method illustrated in FIG. 9. Thereafter, in the second example of the manufacturing method, as illustrated in FIG. 15, a masking layer MK2 is formed on the surface of the semiconductor substrate SB. The masking layer MK2 includes an opening OP so that a portion of the semiconductor substrate SB is exposed from the opening OP.

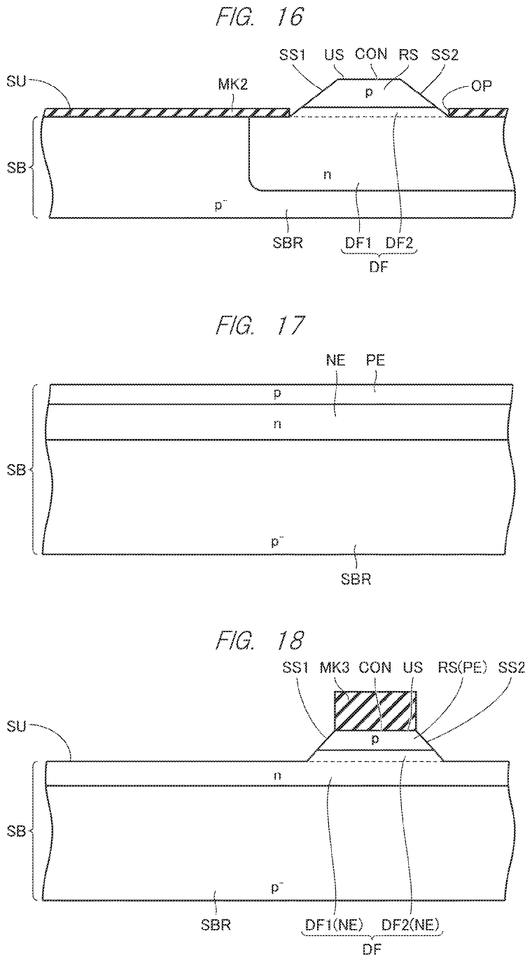

As illustrated in FIG. 16, an epitaxial growth is selectively performed on the surface of the semiconductor substrate SB exposed from the opening OP of the masking layer MK2. In this manner, the convex portion CON is formed in the opening OP of the masking layer MK2. By adjusting conditions of the epitaxial growth, the trapezoidal convex portion CON having the both side surfaces SS1 and SS2 of the (111) plane is formed.

At a lower portion in the convex portion CON, the n-type second semiconductor region DF2 is formed. In this manner, the n-type drift region DF formed of the first semiconductor region DF1 and the second semiconductor region DF2 is formed. The p-type resurf region RS is formed in an upper portion of the convex portion CON. The p-type resurf region RS is formed so as to form a pn junction with the second semiconductor region DF2. The pn junction between the p-type resurf region RS and the second semiconductor region DF2 is located in the convex portion CON. Thereafter, the masking layer MK2 is removed.

Thereafter, the second example of the manufacturing method takes the same steps as those of the first example of the manufacturing method illustrated in FIGS. 12 to 14 and FIG. 2. In this manner, the LDMOS transistor TR according to the present embodiment illustrated in FIG. 2 is formed.

### Third Example of Manufacturing Method

As illustrated in FIG. 17, in a third example of the manufacturing method, an n-type epitaxial layer NE and a p-type epitaxial layer PE are formed collectively in this order on the surface of the semiconductor substrate SB by an epitaxial growth.

As illustrated in FIG. 18, a masking layer MK3 formed of, for example, a silicon oxide film is formed on the p-type epitaxial layer PE. Using the masking layer MK3 as a mask, an anisotropic wet etching using, for example, a TMAH aqueous solution is performed. By this etching, the surface of the semiconductor substrate SB is selectively removed to a position deeper than the pn junction between the p-type epitaxial layer PE and the n-type epitaxial layer NE.

In this anisotropic wet etching, a dependence on the crystal orientation is large, an etching rate in the <100> direction is faster in the case of silicon, and an etching rate in the <111> direction is the slowest. Therefore, by an anisotropic wet etching using a silicon substrate of (100) plane, the convex portion CON having the both side surfaces SS1 and SS2 of (111) plane is formed. In this manner, the trapezoidal convex portion CON including the both side surfaces SS1 and SS2 inclined with respect to the surface SU of the semiconductor substrate SB, and the upper surface US connecting the upper ends of the both side surfaces SS1 and SS2 is formed.

By the above-described etching, in the upper portion of the convex portion CON, the p-type resurf region RS formed of the p-type epitaxial layer PE is formed. In addition, in a lower portion of the convex portion CON, an n-type second semiconductor region DF2 formed of a part of the n-type epitaxial layer NE is formed. Also, below the convex portion CON, the n-type first semiconductor region DF1 formed of a part of the n-type epitaxial layer NE is formed. The n-type drift region DF is formed of the first semiconductor region DF1 and the second semiconductor region DF2. The pn junction between the p-type resurf region RS and the second semiconductor region DF2 is located in the convex portion CON. Thereafter, the masking layer MK3 is removed.

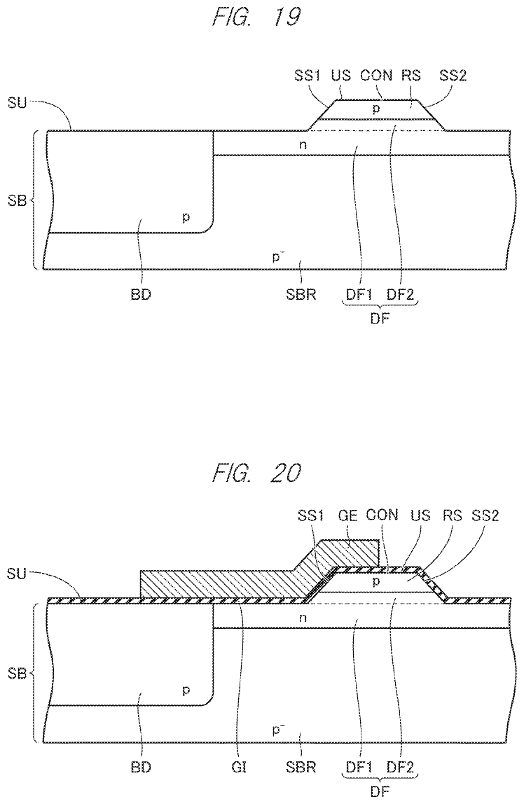

As illustrated in FIG. 19, a p-type body region BD is formed in the semiconductor substrate SB. The p-type body region BD is formed to have a p-type impurity concentration higher than the p-type impurity concentration of the p⁻-type substrate region SBR.

As illustrated in FIG. 20, the surface SU of the semiconductor substrate SB is oxidized. In this manner, so as to cover the surface SU of the semiconductor substrate SB and the surface of the convex portion CON, the gate insulating layer GI formed of a silicon oxide film is formed.

Thereafter, on the gate insulating layer GI, a polycrystalline silicon layer GE into which impurities are implanted is formed. The polycrystalline silicon layer GE is patterned by a photolithography technique and an etching technique to form the gate electrode GE.

As illustrated in FIG. 21, n-type impurities are ion-implanted into the surface SU of the semiconductor substrate SB to form the n⁺-type source region SR and the n⁺-type drain region DR in the surface SU of the semiconductor substrate SB. In addition, p-type impurities are ion-implanted into the surface SU of the semiconductor substrate SB to form the p⁺-type contact region CO in the surface SU of the semiconductor substrate SB.

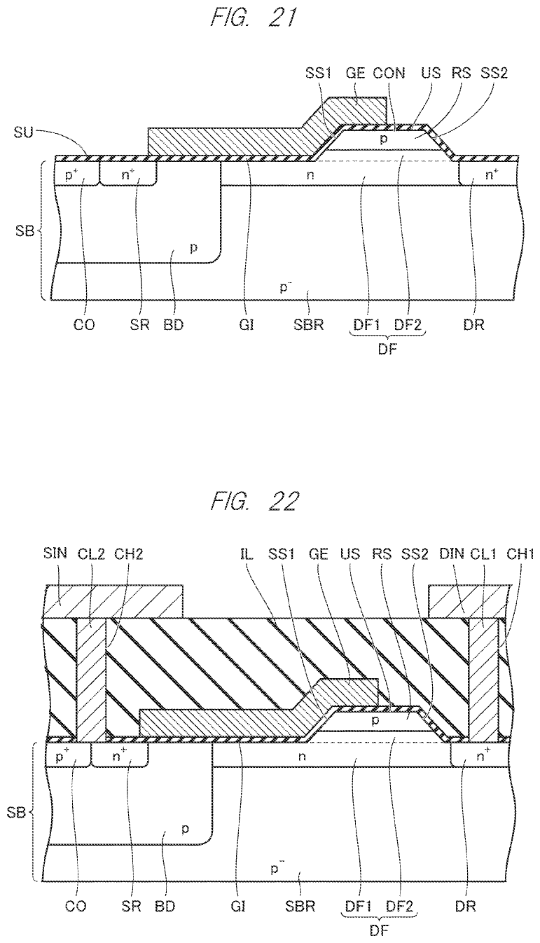

As illustrated in FIG. 22, the interlayer insulating layer IL is formed so as to cover the surface of the semiconductor substrate SB. Contact holes CH1 and CH2 are formed in the interlayer insulating layer IL. Conductive layers CL1 and CL2 are formed to be embedded in the contact holes CH1 and CH2, respectively. Thereafter, the wiring layers DIN and SIN are formed on the interlayer insulating layer IL. In this manner, the LDMOS transistor TR according to the present embodiment is formed.

### Fourth Example of Manufacturing Method

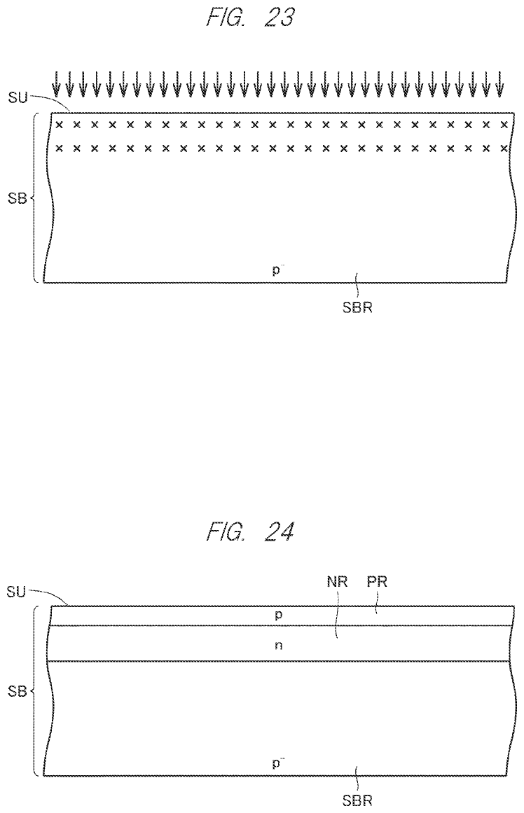

As illustrated in FIG. 23, in a fourth example of the manufacturing method, for example, each of phosphorus (P) and boron (B) is implanted into the surface SU of the semiconductor substrate SB by an ion implantation method. At this time, phosphorus is implanted into a deeper position from the surface SU of the semiconductor substrate SB than boron.

As illustrated in FIG. 24, ion implantation is followed by an annealing to activate the implanted ions. By this annealing, phosphorus and boron are diffused and activated in the semiconductor substrate SB. As a result, a diffusion region NR of n-type impurities (e.g., phosphorus) and a diffusion region PR of p-type impurities (e.g., boron) are formed in the semiconductor substrate SB. The diffusion region NR is formed on the p⁻-type substrate region SBR to form a pn junction with the p⁻-type substrate region SBR. The diffusion region PR is formed in the surface SU of the semiconductor substrate SB and on the diffusion region NR so as to form a pn junction with the diffusion region NR.

Thereafter, in the fourth example of the manufacturing method, steps similar to the steps of the third example of the manufacturing method illustrated in FIGS. 18 to 22 are performed to form the LDMOS transistor TR according to the present embodiment illustrated in FIG. 22.

<Effects>

Next, effects of the present embodiment will be described.

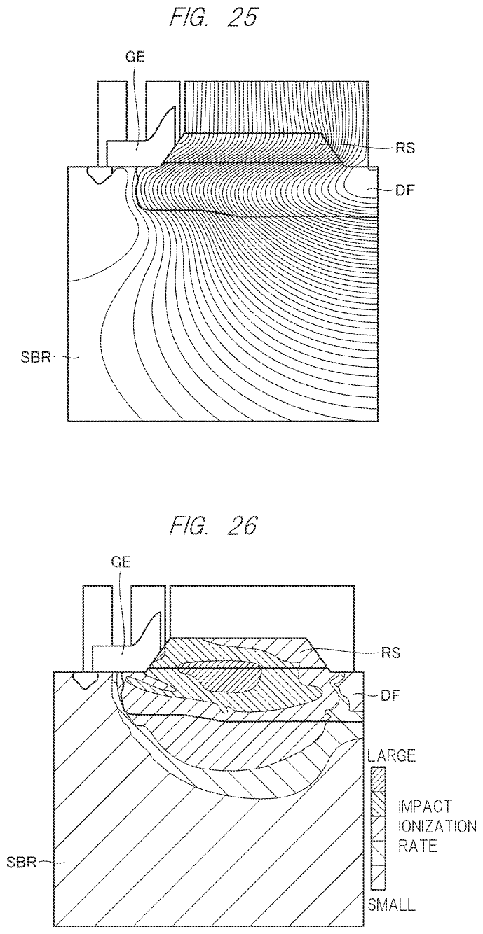

The inventors have investigated a device simulation about a potential profile when a breakdown voltage BVdss between a drain and a source is about 47V in the configuration illustrated in FIG. 2. Thereby, a result illustrated in FIG. 25 was obtained.

From the result of FIG. 25, in the present embodiment, it was found that the depletion layer is spread over almost the entire area of the p-type resurf region RS and the n-type drift region DF. And, it was proven that the distances of the equipotential lines in the depletion layer were almost the same, and that the potential distribution in the depletion layer became almost uniform. Thus, in the present embodiment, it was found that it is possible to design high breakdown voltage efficiently.

The inventors have also investigated an impact ionization rate distribution in the configuration illustrated in FIG. 2 by a device simulation. Thereby, a result illustrated in FIG. 26 was obtained.

From the result of FIG. 26, in the present embodiment, it was found that the impact ionization rate distribution is higher in the vicinity of the pn junction between the p-type resurf region RS and the n-type drift region DF rather than at the surface of the semiconductor substrate SB. As a result, it has been found that the present embodiment is advantageous also in ensuring reliability.

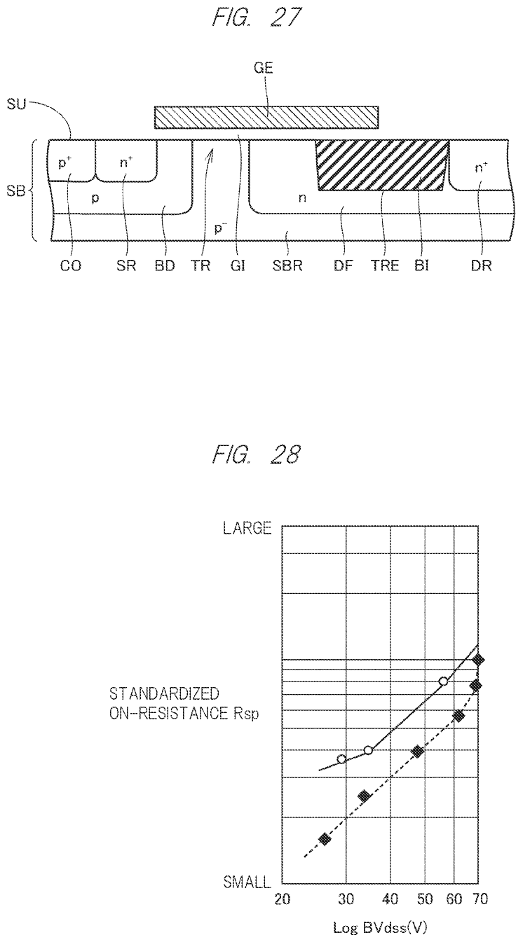

In addition, the inventors have investigated a relationship between the breakdown voltage BVdss and the on-resistance Rsp for each of the configuration of the present embodiment illustrated in FIG. 2 and a configuration of a comparative example illustrated in FIG. 27. Thereby, a result illustrated in FIG. 28 was obtained.

In the comparative example illustrated in FIG. 27, the convex portion CON and the p-type resurf region RS are not provided on the surface SU of the semiconductor substrate SB. And, an STI structure is arranged adjacent to the n⁺-type drain region DR in the n-type drift region DF. The STI structure includes a trench TRE provided in the surface SU of the semiconductor substrate SB, and an insulating layer BI embedded in the trench TRE. The gate electrode GE is extended to above the STI structure via the gate insulating layer GI.

Since the configuration of the comparative example illustrated in FIG. 27 is substantially the same as the configuration of the present embodiment illustrated in FIG. 2 except for the above-described configuration, the same elements are denoted by the same reference numerals, and description thereof will not be repeated.

Data indicated by white circles in FIG. 28 is data of the comparative example illustrated in FIG. 27. The data indicated by the black diamond shapes is the data of the present embodiment illustrated in FIG. 2.

From the result of FIG. 28, it can be seen that, in the range where the breakdown voltage BVdss is 20V to 70V, when the breakdown voltage BVdss is the same with respect to the configuration of the comparative example illustrated in FIG. 27, the on-resistance Rsp is reduced in the configuration of the present embodiment illustrated in FIG. 2. Thus, in the present embodiment, it can be seen that the trade-off between the breakdown voltage BVdss and the on-resistance Rsp is improved. It was also found that the effect of improving the trade-off between the breakdown voltage BVdss and the on-resistance Rsp in the present embodiment is more significant when the breakdown voltage BVdss is within 20V to 60V.

As described above, according to the present embodiment illustrated in FIG. 2, it is possible to achieve both a high breakdown voltage and a low on-resistance. This is based on the fact that, in the present embodiment, as illustrated in FIG. 2, the p-type resurf region RS is arranged in the convex portion CON on the surface of the semiconductor substrate SB. That is, since the p-type resurf region RS is arranged in the convex portion CON, there is no loss of the channel width of LDMOS transistor TR by the p-type resurf region RS, and the current path between the source and drain is not hindered. Therefore, a lower on-resistance is realized in the LDMOS transistor TR. Further, since the p-type resurf region RS is provided, the potential distribution in the depletion layer becomes substantially uniform as illustrated in FIG. 25, and thus a high breakdown voltage is realized.

Further, since the potential distribution in the depletion layer becomes substantially uniform as illustrated in FIG. 25, it is possible to obtain a high breakdown voltage even when the n-type impurity concentration of the drift region DF is increased. As a result, since the n-type impurity concentration in the drift region DF can be increased, the on-resistance can be reduced.

Further, according to the present embodiment, as illustrated in FIG. 3, the drift region DF includes the second semiconductor region DF2 arranged in the convex portion CON. In this manner, the surface SU of the semiconductor substrate SB is located at a lower position by the distance T1 than the height position of the pn junction between the n-type drift region DF and the p-type resurf region RS. Therefore, in a state where no voltage is applied to each of the n-type drift region DF and the p-type resurf region RS, extension of the depletion layer generated in the pn junction between the n-type drift region DF and the p-type resurf region RS to a lower position than the height position of the surface SU of the semiconductor substrate SB is suppressed. Therefore, it is also suppressed that the on-current becomes less likely to flow due to the depletion layer extending below the height position of the surface SU of the semiconductor substrate SB as a barrier. Therefore, it is possible to further improve the on-current (reduction of the on-resistance).

According to the present embodiment, as illustrated in FIG. 2, the first semiconductor region DF1 and the second semiconductor region DF2 configuring the n-type drift region DF have the same n-type impurity concentration. As a result, the second semiconductor region DF2 having the same impurity concentration as the impurity concentration of the first semiconductor region DF1 is located in the convex portion CON. Therefore, the depletion layer generated in the pn junction between the n-type drift region DF and the p-type resurf region RS is suppressed from extending below the height position of the surface SU of the semiconductor substrate SB, and it is possible to improve the on-current (reduction of the on-resistance).

Also, according to the present embodiment, as illustrated in FIG. 4 or FIG. 8, the p-type resurf region RS is electrically connected to any one of the gate electrode GE and the ground potential. As a result, a resurf effect by the p-type resurf region RS can be obtained.

Further, according to the present embodiment, as illustrated in FIG. 2, the p-type impurity concentration in the p-type resurf region RS is equal to or larger than an n-type impurity concentration of the drift region DF. This makes it easy to ensure a charge balance in the depletion layer.

Further, according to the present embodiment, as illustrated in FIG. 2, the side surface of the convex portion CON is an inclined surface of the {111} plane. In this manner, an angle of the gate electrode GE formed on the convex portion CON is reduced, so that an electric field at this site is relaxed, and thus it is possible to achieve a high breakdown voltage.

Further, as illustrated in FIG. 2, according to the present embodiment, the gate electrode GE is formed on the convex portion CON. In this manner, the electric field is relaxed as described above, and it is thus possible to achieve a high breakdown voltage.

Further, according to the present embodiment, as illustrated in FIG. 4, in plan view, the convex portion CON is arranged so as to individually surround the n⁺-type drain region DR and the n⁺-type source region SR. In this manner, it is possible to effectively obtain the resurf effect by the p-type resurf region RS.

In addition, when the contact conductive layer CL3 connected to the p-type resurf region RS is arranged in a vicinity of the n⁺-type drain region DR, there is a possibility that the breakdown voltage BVdss is lowered. However, according to the present embodiment, as illustrated in FIG. 4, the contact conductive layer CL3 connected to the p-type resurf region RS is arranged in a second direction D2 that is perpendicular to the first direction D1 toward the n⁺-type drain region DR with respect to the n⁺-type source region SR in plan view. As a result, since the contact conductive layer CL3 is arranged away from the n⁺-type drain region DR, lowering of the breakdown voltage BVdss can be suppressed.

Further, according to the present embodiment, as illustrated in FIG. 5, the contact conductive layer CL3 connected to the p-type resurf region RS is connected to a flat surface that is the upper surface US of the convex portion CON. Thus, as compared with the case of connecting the contact conductive layer CL3 to the inclined surfaces SS1 and SS2 of the convex portion CON, the connection between the contact conductive layer CL3 and the p-type resurf region RS is facilitated.

In addition, according to the present embodiment, as illustrated in FIG. 4, the n⁺-type drain region DR is arranged having the distance W from the p-type resurf region RS in plan view. This makes it possible to suppress a decrease in breakdown voltage due to reach-through.

According to the present embodiment, the gate electrode GE has any one of the ring shape as illustrated in FIG. 6 and the ladder shape as illustrated in FIG. 7. Thus, it is possible to appropriately select a planar shape of the gate electrode GE.

<Modification>

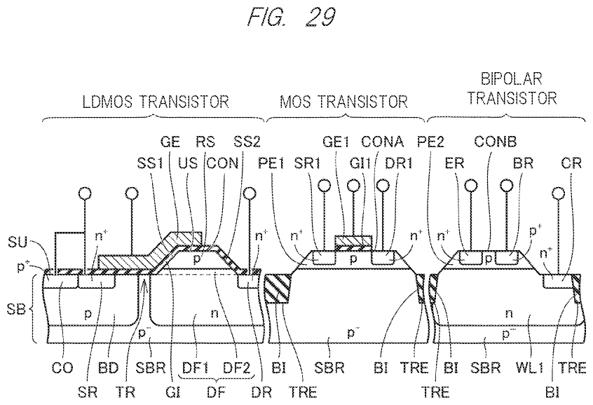

Next, an application example of the semiconductor device according to the present embodiment will be described with reference to FIG. 29.

As illustrated in FIG. 29, the LDMOS transistor TR of the present embodiment is arranged on the semiconductor substrate SB together with, for example, a MOS transistor and a bipolar transistor. In the forming region of each of the MOS transistor and the bipolar transistor, convex portions CONA and CONB are provided on the surface SU of the semiconductor substrate SB. P-type regions PE1 and PE2 are arranged in each of the convex portions CONA and CONB.

In the forming region of the MOS transistor, the n⁺-type source region SR1 and the n⁺-type drain region DR1 are arranged on the upper surface of the convex portion CONA. For this reason, the n⁺-type source region SR1 and the n⁺-type drain region DR1 of the MOS transistor are arranged at a height position that differs from a height position of the n⁺-type source region SR and the drain region DR of the LDMOS transistor TR. In addition, a channel of the MOS transistor is formed at a height position different from a height position of a channel of the LDMOS transistor TR.

In the forming region of the MOS transistor, the gate electrode GE1 is arranged on the upper surface of the convex portion CONA via a gate insulating layer GI1. The gate electrode GE1 is located on the region between the n⁺-type source region SR1 and the n-type drain region DR1.

In the forming region of the bipolar transistor, an n-type region WL1 is arranged in the semiconductor substrate SB. The n-type region WL1 forms a pn junction with the p⁻-type substrate region SBR. In addition, the n-type region WL1 forms a pn junction with the p-type region PE2 in the convex portion CON.

In the forming region of the bipolar transistor, the n⁺-type collector region CR is arranged in the surface SU of the semiconductor substrate SB so as to be adjacent to the n-type region WL1. Therefore, the n⁺-type collector region CR of the bipolar transistor is arranged at the same height position as the n⁺-type source region SR and the n⁺-type drain region DR of the LDMOS transistor TR.

On the other hand, each of an n-type emitter region ER and a p⁺-type base region BR is arranged on an upper surface of the convex portion CONB to form a pn junction with the p-type region PE2. For this reason, the n-type emitter region ER and the p-type base region BR of the bipolar transistor are arranged at a height position different from a height position of the n⁺-type source region SR and the n⁺-type drain region DR of the LDMOS transistor TR.

In this manner, the LDMOS transistor TR of the present embodiment may be arranged together with the MOS transistor and the bipolar transistor. It may be arranged together with other elements.

Although the invention made by the present inventors has been specifically described based on the embodiments, the present invention is not limited to the embodiments described above, and it is needless to say that various modifications can be made without departing from the gist thereof.

What is claimed is:

1. A semiconductor device comprising:
a semiconductor substrate including a surface and a convex portion protruding upward from the surface;
a gate electrode arranged on the surface of the semiconductor substrate;
a source region of a first conductivity type and a drain region of the first conductivity type, the source region and the drain region being arranged on the semiconductor substrate;
a first region of the first conductivity type arranged in the semiconductor substrate so as to be positioned between the gate electrode and the drain region in plan view, the first region having an impurity concentration lower than an impurity concentration of the drain region; and
a second region of a second conductivity type arranged in the convex portion, the second region forming a pn junction with the first region.

2. The semiconductor device according to claim 1,
wherein the first region includes:
a first semiconductor region arranged below the convex portion; and
a second semiconductor region arranged in the convex portion so as to form a pn junction with the second region.

3. The semiconductor device according to claim 2,
wherein an impurity concentration of the first conductivity type in the second semiconductor region is equal to an impurity concentration of the first conductivity type in the first semiconductor region.

4. The semiconductor device according to claim 1,
wherein the second region is electrically connected to any one of the gate electrode and a ground potential.

5. The semiconductor device according to claim 1,
wherein an impurity concentration of the second conductivity type in the second region is equal to or larger than the impurity concentration of the first conductivity type in the first region.

6. The semiconductor device according to claim 1,
wherein a side surface of the convex portion is configured by an inclined surface of {111} plane.

7. The semiconductor device according to claim 1,
wherein the gate electrode is formed on the convex portion.

8. The semiconductor device according to claim 1,
wherein the convex portion is arranged so as to individually surround a periphery of each of the drain region and the source region in plan view.

9. The semiconductor device according to claim 8, comprising a contact conductive layer connected to the second region,
wherein the contact conductive layer is arranged in a second direction perpendicular to a first direction toward the drain region with respect to the source region in plan view.

10. The semiconductor device according to claim 9,
wherein the convex portion includes:
both side surfaces to be inclined surfaces in a cross section; and
an upper surface which is a flat surface connected to an upper end of each of the both side surfaces, and
wherein the contact conductive layer is connected to the upper surface of the convex portion.

11. The semiconductor device according to claim 1,
wherein the drain region is arranged at a distance from the second region in plan view.

12. The semiconductor device according to claim 1,
wherein the gate electrode has either a ring shape or a ladder shape in plan view.

13. The semiconductor device according to claim 1, comprising a second transistor different from the first transistor, the first transistor including the source region, the drain region and the gate electrode,
wherein a source region of the second transistor and a drain region of the second transistor are arranged at a height position different from a height position of the source region of the first transistor and a height position of the drain region of the first transistor.

14. A semiconductor device comprising:
a semiconductor substrate including a surface, a first convex portion, and a second convex portion, the first convex portion and the second convex portion protruding upward from the surface;
a first transistor having a first source region of a first conductivity type, a first drain region of the first conductivity type, a drift region of the first conductivity type, and a resurf region of a second conductivity type; and
a second transistor having a second source region and a second drain region,
wherein the resurf region is arranged in the first convex portion so as to form a pn junction with the drift region, and
wherein the second source region and the second drain region are arranged in the second convex portion at a height position different from a height position of the first source region and a height position of the first drain region.

15. A method of manufacturing a semiconductor device comprising:
forming a semiconductor substrate including a surface, a convex portion protruding upward from the surface, a first region of a first conductivity type arranged below the convex portion, and a second region of a second conductivity type arranged in the convex portion so as to form a pn junction with the first region;
forming a gate electrode on the surface of the semiconductor substrate; and
forming a source region of the first conductivity type and a drain region of the first conductivity type in the semiconductor substrate so as to sandwich the first region, the source region and the drain region each having an impurity concentration of the first conductivity type higher than an impurity concentration of the first region.

16. The method according to claim 15,
wherein the convex portion is formed by selectively removing the surface of the semiconductor substrate by an etching.

17. The method according to claim 15,
wherein the convex portion is formed by subjecting the surface of the semiconductor substrate to selective epitaxial growth.
